(19) United States
(12) Patent Application Publication
(10) Pub. No.: US 2013/0221535 A1
(43) Pub. Date: Aug. 29, 2013

(54) Diffusion Barrier Layer, Metal Interconnect Arrangement and Method of Manufacturing the Same

(71) Applicants: Xiaolong Ma, Beijing (CN); Huaxiang Yin, Beijing (CN); Lichuan Zhao, Beijing (CN)

(72) Inventors: Xiaolong Ma, Beijing (CN); Huaxiang Yin, Beijing (CN); Lichuan Zhao, Beijing (CN)

(21) Appl. No.: 13/517,050

(22) PCT Filed: Feb. 29, 2012
(86) PCT No.: PCT/CN2012/071761

§ 371 Date: Jun. 19, 2012

(30) Foreign Application Priority Data
Feb. 24, 2012 (CN) 201210044177.2

(51) Int. Cl. H01L 23/48; B32B 9/00; H01L 21/768

(52) U.S. Cl. 257/774; 438/675; 428/408; 257/E23.011; 257/E21.586

(57) ABSTRACT

A diffusion barrier layer, a metal interconnect arrangement and a method of manufacturing the same are disclosed. In one embodiment, the metal interconnect arrangement may comprise a conductive plug/interconnect wire for electrical connection, and a diffusion barrier layer provided on at least a portion of a surface of the conductive plug/interconnect wire. The diffusion barrier layer may comprise insulating amorphous carbon.

### TECHNICAL FIELD

The present disclosure relates to the semiconductor field, and more particularly, to a diffusion barrier layer, a metal interconnect arrangement and a method of manufacturing the same.

### BACKGROUND

In the semiconductor manufacture industry, silicon nitride fabricated by means of Plasma Enhanced Chemical Vapor Deposition (PECVD) or High Density Plasma Chemical Vapor Deposition (HDPCVD), with a dielectric constant K>7, is widely used in metal interconnect arrangements due to its properties such as high compactness, high reliability, and chemical stability. For example, silicon nitride can be used for a passivation layer, a hard mask, a barrier layer against diffusion of moving ions and water molecules, an etching stop layer, a polishing stop layer, a dielectric layer for blocking oxidation and diffusion of metal, and the like. However, silicon nitride has a so great dielectric constant that its applications to the most advanced semiconductor manufacture industry are limited.

To reduce an effective dielectric constant for an inter-layer dielectric of a metal interconnect arrangement, different dielectric materials for diffusion barrier such as SiC (K=3.9), SiCN (K=5.0), and SiCO (K=4.2) are getting more researches and applications. However, with further thinning of the ILD, the dielectric constant of the dielectric materials for diffusion barrier is becoming a more significant contribution to the effective dielectric constant.

### SUMMARY

The present disclosure provides, among others, a diffusion barrier layer, a metal interconnect arrangement and a method of manufacturing the same.

According to one aspect of the present disclosure, a metal interconnect arrangement is disclosed. The metal interconnect arrangement may comprise a conductive plug/interconnect wire for electrical connection, and a diffusion barrier layer provided on at least a portion of a surface of the conductive plug/interconnect wire. The diffusion barrier layer may comprise insulating amorphous carbon.

According to another aspect of the present disclosure, a method of manufacturing a metal interconnect arrangement is disclosed. The method may comprise forming a diffusion barrier layer on at least a portion of a surface of a conductive plug/interconnect wire. The diffusion barrier layer may comprise insulating amorphous carbon.

According to a still further aspect of the present disclosure, there is provided a diffusion barrier layer, which may be provided between a metal arrangement and a dielectric material to prevent inter-diffusion between the metal arrangement and the dielectric material. The diffusion barrier layer may comprise insulating amorphous carbon.

### BRIEF DESCRIPTION OF THE DRAWINGS

The above and other objects, features, and advantages of the present disclosure will become apparent from following descriptions of embodiments with reference to the attached drawings, in which:

FIGS. 1-4 are schematic views showing a flow of manufacturing a metal interconnect arrangement according to an embodiment of the present disclosure;

FIGS. 5-8 are schematic views showing a flow of manufacturing a metal interconnect arrangement according to a further embodiment of the present disclosure; and

FIGS. 9-13 are schematic views showing a flow of manufacturing a metal interconnect arrangement according to a still further embodiment of the present disclosure.

### DETAILED DESCRIPTION

Hereinafter, descriptions are given with reference to embodiments shown in the attached drawings. However, it is to be understood that these descriptions are illustrative and not intended to limit the present disclosure. Further, in the following, known structures and technologies are not described to avoid obscuring the present disclosure unnecessarily.

In the drawings, various structures according to the embodiments are schematically shown. However, they are not drawn to scale, and some features may be enlarged while some features may be omitted for sake of clarity. Moreover, shapes and relative sizes and positions of regions and layers shown in the drawings are also illustrative, and deviations may occur due to manufacture tolerances and technique limitations in practice. Those skilled in the art can also devise regions/layers of other different shapes, sizes, and relative positions as desired.

In the context of the present disclosure, when a layer/element is recited as being “on” a further layer/element, the layer/element can be disposed directly on the further layer/element, or otherwise there may be an intervening layer/element interposed there in between. Further, if a layer/element is “on” a further layer/element in an orientation, then the layer/element can be “under” the further layer/element when the orientation is turned.

The inventors have recognized that insulating amorphous carbon can be used for diffusion barrier. Therefore, according to an embodiment of the present disclosure, a diffusion barrier layer may comprise insulating amorphous carbon, and may be disposed between a metal arrangement and a dielectric material to effectively prevent inter-diffusion between the metal arrangement and the dielectric material.

According to a further embodiment of the present disclosure, such a diffusion barrier layer is applicable to a metal interconnect arrangement. The metal interconnect arrangement may comprise a conductive plug/interconnect wire for electrical connection. The conductive plug/interconnect wire may have a diffusion barrier layer comprising insulating amorphous carbon formed on at least a portion of a surface thereof. More specifically, the conductive plug/interconnect wire may be embedded in an inter-layer dielectric layer. For example, the diffusion barrier layer comprising insulating amorphous carbon may be provided on a bottom surface of the inter-layer dielectric layer to prevent inter-diffusion between the conductive plug/interconnect wire and an underlying dielectric layer. In this case, the conductive plug/interconnect wire may be electrically connected to an underlying conductive component though an opening in the diffusion barrier layer. In addition or instead, the diffusion barrier layer comprising insulating amorphous carbon may be formed on a side surface of the conductive plug/interconnect wire, for example, to prevent inter-diffusion between the conductive plug/interconnect wire and the inter-layer dielectric layer. Further, in addition or instead, the diffusion barrier layer comprising insulating amorphous carbon may be formed on a top surface of the inter-layer dielectric layer, for example, to prevent inter-diffusion between the conductive plug/interconnect wire and an overlying dielectric layer. In this case, the conductive plug/interconnect wire may be electrically connected to an overlying conductive component though an opening in the diffusion barrier layer. The diffusion barrier layer can reduce an effective dielectric constant of the metal interconnect arrangement, and preferably can improve the heat conduction performance.

According to a further embodiment of the present disclosure, a method of manufacturing a metal interconnect arrangement may comprise preparing a diffusion barrier layer from insulating amorphous carbon. Specifically, the metal interconnect arrangement may comprise a conductive plug/interconnect wire for electrical connection, which may be embedded in an inter-layer dielectric layer. The diffusion barrier layer comprising insulating amorphous carbon may be formed on at least a portion of a surface of the conductive plug/interconnect wire.

For example, the diffusion barrier layer comprising insulating amorphous carbon may be formed on a bottom surface of the conductive plug/interconnect wire. In this case, a preliminary diffusion barrier layer may be provided on a bottom surface of the inter-layer dielectric layer. Then, the inter-layer dielectric layer and the preliminary diffusion barrier layer may be patterned to form a trench therein, into which a conductive material is filled to form the conductive plug/interconnect wire. The preliminary diffusion barrier layer may be patterned in such a manner that an opening is formed therein, through which opening the conductive plug/interconnect wire is electrically connected to an underlying conductive component. The patterned preliminary diffusion barrier layer constitutes the diffusion barrier layer on the bottom surface of the conductive plug/interconnect wire.

Alternatively, the diffusion barrier layer comprising insulating amorphous carbon may be formed on a side surface of the conductive plug/interconnect wire, for example. In this case, the inter-layer dielectric layer may be patterned to form a trench therein, and the diffusion barrier layer may be formed on a side wall or side walls of the trench. Then, a conductive material may be filled into the trench to form the conductive plug/interconnect wire.

Alternatively, the diffusion barrier layer comprising insulating amorphous carbon may be formed on a top surface of the conductive plug/interconnect wire, for example. In this case, a preliminary diffusion barrier layer may be provided on a top surface of the inter-layer dielectric layer after the conductive plug/interconnect wire has been formed in the inter-layer dielectric layer. The preliminary diffusion barrier layer may be patterned in such a manner that an opening is formed therein, through which opening the conductive plug/interconnect wire is electrically connected to an overlying conductive component. The patterned preliminary diffusion barrier layer constitutes the diffusion barrier layer on the top surface of the conductive plug/interconnect wire.

According to embodiments of the present disclosure, it is possible to effectively prevent metal diffusion by means of the diffusion barrier layer comprising insulating amorphous carbon. Further, because insulating amorphous carbon has a very low dielectric constant, it is possible to reduce the effective dielectric constant of the inter-layer dielectric of the metal interconnect arrangement to, for example, 6 or less. Furthermore, insulating amorphous carbon has good heat conduction and mechanical performances, and thus it is possible to enhance the heat conduction performance of the inter-layer dielectric and improve the mechanical performance of the metal interconnect arrangement.

The present disclosure can be presented in various forms, and some examples thereof will be described hereinafter.

A flow of manufacturing a metal interconnect arrangement according to an embodiment of the present disclosure will be described with reference to FIGS. 1-4.

FIG. 1 schematically shows a general semiconductor arrangement 10 after the Front End Of Line (FEOL), wherein FIG. 1(a) is a top view, and FIG. 1(b) is a partial section view taken along line aa′ in FIG. 1(a). As shown in FIG. 1, the semiconductor arrangement 10 may comprise a substrate 100 and a semiconductor device or semiconductor devices (not shown) formed on the substrate 100. The semiconductor device or devices may comprise terminal(s) for electric connection(s) with the outside (for example, a gate terminal of a transistor device), or contact(s) formed on the terminal(s) (for example, contacts formed on source/drain terminals of a transistor device). In the following, descriptions are given with respect to a contact 106 formed in a dielectric layer 102 on the substrate 100, by way of example. Here, the dielectric layer 102 can be called as a “Pre-Metal Dielectric” (PMD) layer, because it is formed before the metal interconnect process. For example, the dielectric layer 102 may comprise, but not limited to, silicon dioxide. The contact 106 may have at least one surface thereof exposed by planarization such as Chemical Mechanical Polishing (CMP), for which surface a metal interconnect arrangement is to be manufactured to electrically contact therewith.

The “semiconductor device(s)” as used herein may comprise any suitable semiconductor devices, comprising, but not limited to, a Complementary Metal Oxide Semiconductor Field Effect Transistor (CMOSFET), a Bipolar Junction Transistor (BJT), a High Electron Mobility Transistor (HEMT), a Tunneling Field Effect Transistor (TFET), and the like, for example.

Here, in order to, for example, facilitate patterning and/or protecting the PMD 102, a hard mask/protection layer 104 may be formed on the PMD 102. For example, the hard mask/protection layer 104 may comprise, but not limited to, SiN, SiC, and the like. According to an example of the present disclosure, the hard mask/protection layer 104 may comprise insulating amorphous carbon.

Those skilled in the art should appreciate that the semiconductor arrangement 10 shown in FIG. 1 can be obtained in various ways through the FEOL. Details of the manufacture of the semiconductor arrangement 10 are omitted here.

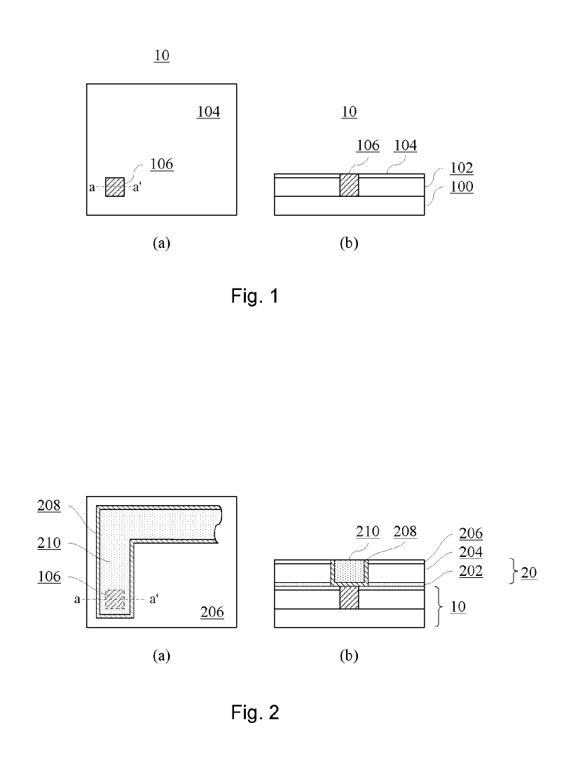

FIG. 2 schematically shows a first interconnect layer 20 formed on the semiconductor arrangement 10 according to an embodiment of the present disclosure, wherein FIG. 2(a) is a top view, and FIG. 2(b) is a partial section view taken along line aa′ in FIG. 2(a). As shown in FIG. 2, a first diffusion barrier layer 202 and a first inter-layer dielectric (ILD) layer 204 may be formed sequentially on the semiconductor arrangement 10.

According to an embodiment of the present disclosure, preferably the first diffusion barrier layer 202 may comprise insulating amorphous carbon. For example, insulating amorphous carbon may be deposited by means of Filtered Cathodic Vacuum Arc Deposition (FCVAD) or Plasma Enhanced Chemical Vapor Deposition (PECVD). The first diffusion barrier layer 202 may have a thickness of about 2 nm to about 200 nm, and preferably about 5 nm to 50 nm.

Optionally, a diffusion barrier/protection layer (not shown), such as SiO₂, SiN, and SiC, may be formed on the first diffusion barrier layer 202 by means of, for example, PECVH or HDPCVD.

The first ILD 204 may be formed on the first diffusion barrier layer 202 (or alternatively, on the diffusion barrier/protection layer if this diffusion barrier/protection layer is formed as described above) by means of deposition or spin coating, for example. According to an embodiment, the first ILD 204 may comprise dielectric of a low dielectric constant (K) to reduce a distributed capacitance between layers and delay of signal propagation. Generally, the first ILD 204 can be selected so that its dielectric constant K<3.5, preferably K<3.0, and more preferably K<2.0. For example, the first ILD 204 may comprise, but not limited to, carbon doped silicon dioxide, fluorine doped silicon dioxide, Fluorinated Silicate Glass (FSG), heat-curable organic polymer materials, silicon oxycarbide, SiCOH, Spin On Glass (SOG), Hydrogen SilsesQuioxane (HSQ), Methyl SilsesQuioxane (MSQ), a mixture of HSQ and MSQ, porous dielectric materials, and the like.

Here, in order to improve the adhesion between the first diffusion barrier layer 202 and the first ILD 204, an adhesion improvement layer (not shown) may be formed there in between the layers. Further, in order to facilitate patterning and/or protecting the first ILD 204, a stop/protection layer 206 may be formed on the first ILD 204. The stop/protection layer 206 may also comprise insulating amorphous carbon.

Then, the (optional) stop/protection layer 206, the first ILD 204, and the first diffusion barrier layer 202 may be patterned. For example, a trench pattern corresponding to a conductive arrangement (e.g., a conductive interconnect wire or a conductive plug) to be formed in the first interconnect layer 20 may be transferred to the stop/protection layer 206, the first ILD 204, and the first diffusion barrier layer 202 sequentially by means of photolithography, to form a trench therein. In the case where the hard mask/protection layer 104 is formed, the hard mask/protection layer 104 can serve as an etching stop layer. Subsequently, a conductive material may be filled into the trench by means of, for example, the Damascene process, to form the conductive arrangement (e.g., a conductive interconnect wire or a conductive plug) 210. For example, the conductive material may comprise, but not limited to, metal such as Cu or Al.

Here, to further prevent inter-diffusion, a conductive barrier layer 208 may be formed on bottom and side surfaces of the trench, so that the conductive barrier layer 208 surrounds bottom and side surfaces of the conductive arrangement 210. For example, the conductive barrier layer 208 may comprise, but not limited to, metal, and nitride and carbide thereof, such as Ta/TaN/TaSiN, Ti/TiC/TiN/TiSiN/TiCN, W/WN/WSiN, and Ru/RuC/RuN.

After formation of the conductive barrier layer 208 and the conductive arrangement 210, a planarization process such as CMP may be conducted, to achieve a substantially flat surface, with a top surfaced of the conductive arrangement 210 exposed.

In this way, the first interconnect layer 20 is achieved. As shown in FIG. 2, the first interconnect layer 20 may comprise the first ILD 204, the first diffusion barrier layer 202 provided on the bottom surface of the first ILD 204, and the first conductive arrangement (e.g., a conductive interconnect wire or a conductive plug) 210 embedded in the first ILD 204. In the case where the arrangement underlying the first interconnect layer 20 is the semiconductor arrangement 10 achieved by the FEOL, the first interconnect layer 20 generally comprises a conductive interconnect wire. Further, the first conductive arrangement 210 may be electrically connected to the contact 106 in the underlying semiconductor arrangement 10 through an opening in the first diffusion barrier layer 202. Preferably, the conductive barrier layer 208 is formed on the bottom and side surfaces of the first conductive arrangement 210.

It is to be noted that the conductive arrangement 210 (i.e., the conductive interconnect wire in this example) is shown in FIG. 2(a) as an inverted-L shape. However, this is an illustrative example, and the conductive arrangement 210 may be formed in any desired shapes according to designs.

Further, in the above example, due to the presence of the conductive barrier layer 208, the trench pattern corresponding to the conductive arrangement (e.g., a conductive interconnect wire or a conductive plug) is transferred to the first diffusion barrier layer 202 during patterning. Thus, the first diffusion barrier layer 202 may be absent from the bottom surface of the conductive arrangement 210, while only the conductive barrier layer 208 is provided on the bottom surface of the conductive arrangement 210. In this case, the hard mask/protection layer 104 preferably comprises insulating amorphous carbon. As a result, the bottom surface of the conductive arrangement 210 is separated from the PMD 102 by (the conductive barrier layer 208 and) the hard mask/protection layer 104 comprising insulating amorphous carbon, except a portion thereof at which the conductive arrangement 210 is electrically connected to the contact 106. Thus, the hard mask/protection layer 104 comprising insulating amorphous carbon can serve as a diffusion barrier layer between the conductive arrangement 210 and the PMD 102.

However, the present disclosure is not limited thereto. For example, during patterning, the trench pattern corresponding to the conductive arrangement (e.g., a conductive interconnect wire or a conductive plug) may be transferred to (the stop/protection layer 206 and) the first ILD 204, without being transferred to the first diffusion barrier layer 202. In this case, during the pattern transfer, the first diffusion barrier layer 202 may serve as an etching stop layer. Further, the first diffusion barrier layer 202 may be patterned to have a first opening, through which the conductive arrangement 210 is electrically connected to the underlying contact 106. As a result, the bottom surface of the conductive arrangement 210 has the first diffusion barrier layer 202 formed thereon, except the portion thereof at which the conductive arrangement 210 is electrically connected to the contact 106.

As can be seen from the above, in the first interconnect layer 20, the conductive material (usually, metal) for the conductive arrangement 210 is separated from the underlying PMD 102 by the first diffusion barrier layer 202 (and/or the hard mask/protection layer 104 comprising insulating amorphous carbon). As a result, it is possible to prevent inter-diffusion between the conductive material and the dielectric material. The inter-diffusion may comprise diffusion of metal atoms into the dielectric material (which will impact the reliability of the dielectric material), chemical reaction of oxygen atoms or ions, water molecules, and the like in the dielectric material with the metal (which will reduce the conductivity and reliability of the metal), for example.

After formation of the first interconnect layer 20 as described above, a plurality of interconnect layers may be formed sequentially in the same way, so as to finish the final metal interconnect arrangement for the semiconductor device(s). Patterns of conductive arrangements in the respective interconnect layers are determined based on designs. Generally, an interconnect layer may comprise a conductive interconnect wire, and a further interconnect layer adjacent thereto may comprise a conductive plug or a conductive via.

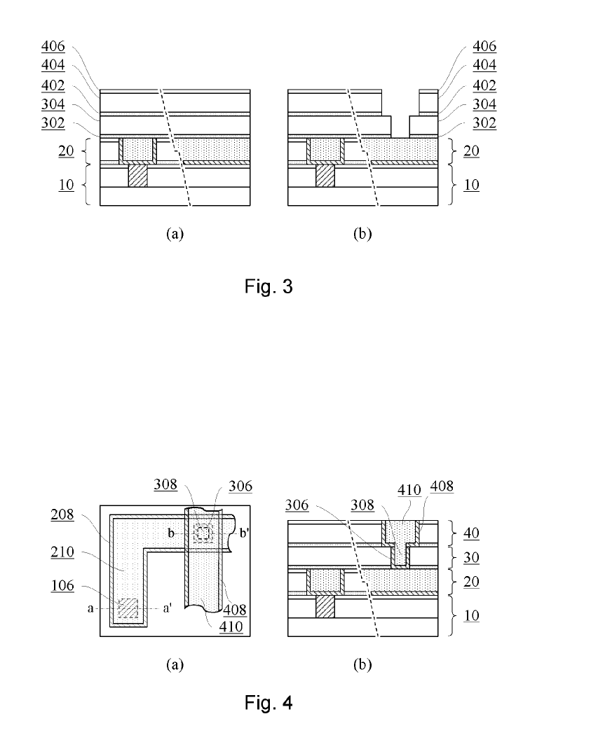

According to an embodiment, patterning of two adjacent interconnect layers may be conducted in one stage, and filling of the two adjacent interconnect layers may be conducted also in one stage, by means of the dual Damascene process, for example. In the following, such process will be explained with reference to examples shown in FIGS. 3 and 4.

As shown in FIG. 3(a), a second diffusion barrier layer 302, a second ILD 304, a third diffusion barrier layer 402, and a third ILD 404 may be formed sequentially on the first interconnect layer 20 by means of deposition, for example. Also, to facilitate patterning and/or protecting the ILD, a stop/protection layer 406 may be formed on the third ILD 404. Those diffusion barrier layers, ILDs, and the stop/protection layer may comprise the same materials as the corresponding layers in the first interconnect layer.

It is to be noted that FIG. 3(a) shows a partial section view taken along line aa′ in the left portion thereof and a partial section view taken along line bb′ (referring to FIG. 4(a)) in the right portion thereof. This is also true for FIGS. 3(b) and 4(b).

Subsequently, as shown in FIG. 3(b), a trench corresponding to a conductive arrangement (referring to 410 shown in FIG. 4) for a third interconnect layer (referring to 40 shown in FIG. 4) may be formed in the stop/protection layer 406, the third ILD 404, and the third diffusion barrier layer 402, and a trench corresponding to a conductive arrangement (referring to 308 shown in FIG. 4) for a second interconnect layer (referring to 30 shown in FIG. 4) may be formed in the second ILD 304 and the second diffusion barrier layer 302, by means of lithography, for example. In this example, the conductive arrangement for the second interconnect layer may comprise a conductive plug (or a conductive via), and the conductive arrangement for the third interconnect layer may comprise a conductive interconnect wire, so that the conductive plug (or the conductive via) connects the conductive interconnect wire for the first interconnect layer and the conductive interconnect wire for the third interconnect layer.

Next, as shown in FIG. 4, a conductive barrier layer shown as 306 and 408 may be formed on side and bottom surfaces of the trenches, into which a conductive material may be filled to form the conductive arrangements (i.e., the conductive interconnect wire and the conductive plug) 308 and 410.

Thus, the second interconnect layer 30 and the third interconnect layer 40 are formed. As shown in FIG. 4, the second interconnect layer 30 may comprise the second ILD 304, the second diffusion barrier layer 302 provided on a bottom surface of the second ILD 304, and the second conductive arrangement 308 (e.g., the conductive plug or via in this example) embedded in the second ILD 304. The second conductive arrangement 308 may have the conductive barrier layer 306 on its bottom and side surfaces. The second conductive arrangement 308 may be electrically connected to the underlying conductive arrangement 210 through a second opening in the second diffusion barrier layer 302. Further, the third interconnect layer 40 may comprise the third ILD 404, the third diffusion barrier layer 402 provided on a bottom surface of the third ILD 404, and the third conductive arrangement 410 (e.g., the conductive interconnect wire in this example) embedded in the second ILD 404. The third conductive arrangement 410 may have the conductive barrier layer 408 on its bottom and side surfaces. The third conductive arrangement 410 may be electrically connected to the underlying conductive arrangement 308 through a third opening in the third diffusion barrier layer 402.

In the examples shown in FIGS. 3 and 4, the second conductive arrangement 308 and the third conductive arrangement 410 may be integrally formed by the dual Damascene process, for example. Further, the second conductive barrier layer 306 and the third conductive barrier layer 408 may be integrally formed. In this case, the conductive barrier layer (306, 408) is provided on the bottom and side surfaces of the integral conductive arrangement (308, 410).

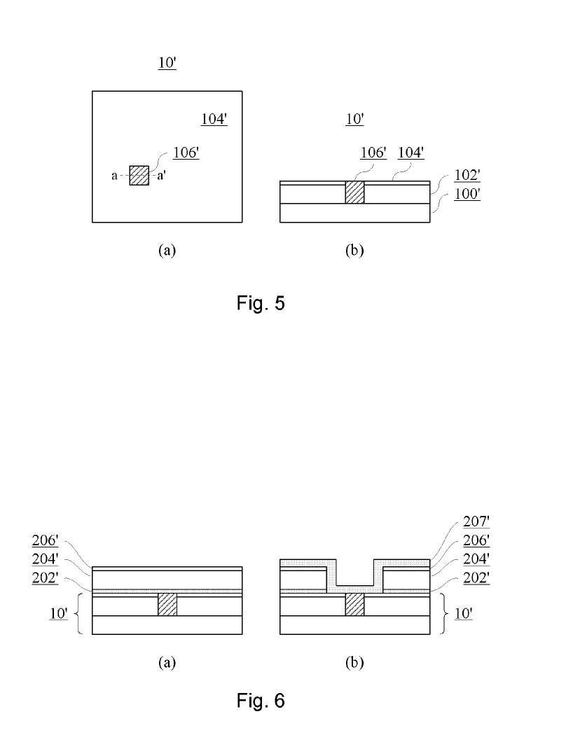

Next, a flow of manufacturing a metal interconnect arrangement according to a further embodiment of the present disclosure will be described with reference to FIGS. 5-8. This flow according to the further embodiment differs from the flow described above with reference to FIGS. 1-4 manly in that a side diffusion barrier layer is further formed on a side surface of a conductive arrangement. In the following, descriptions are provided mainly with respect to differences of this embodiment from the above embodiment. Further, reference symbols “xx′” shown in FIGS. 5-8 refer to the same components as those indicated by reference symbols “xx” in FIGS. 1-4.

Likewise, FIG. 5 schematically shows a general semiconductor arrangement 10′ after the FEOL. The semiconductor arrangement 10′ is identical to the semiconductor arrangement 10 shown in FIG. 1. For components of the semiconductor arrangement 10′, reference may be made to the above descriptions in conjunction with FIG. 1, and detailed descriptions thereof are omitted here.

Next, as shown in FIG. 6(a), a first diffusion barrier layer 202′, a first ILD 204′, and an optional stop/protection layer 206′ may be formed sequentially on the semiconductor arrangement 10′. For those layers, reference may be also made to the above descriptions in conjunction with FIG. 1, and detailed descriptions thereof are omitted here.

Then, as shown in FIG. 6(b), a trench pattern corresponding to a conductive arrangement (e.g., a conductive interconnect wire or a conductive plug) to be formed in a first interconnect layer may be transferred to the stop/protection layer 206′, the first ILD 204′, and the first diffusion barrier layer 202′ sequentially by means of, for example, photolithography, to form a trench therein. Next, a diffusion barrier material layer 207′ may be isotropically deposited by means of PECVD, for example. The diffusion barrier material layer 207′ may comprise insulating amorphous carbon.

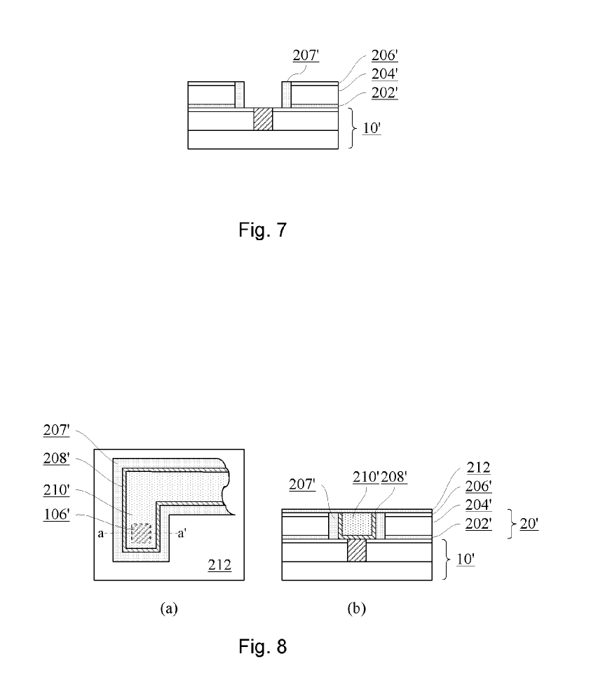

Then, as shown in FIG. 7, the diffusion barrier material layer 207′ may be etched anisotropically by means of, for example, Reactive Ion Etching (RIE), so that the diffusion barrier material layer 207′ is remained on side surfaces of the trench, resulting in a side diffusion barrier layer. (In the case where the diffusion barrier material layer 207′ comprises insulating amorphous carbon, O₂ or Ar may be adopted in RIE.)

Then, the flow may continue in the substantially same way as in the above described embodiment. For example, as shown in FIG. 8, a conductive diffusion barrier layer 208′ may be formed on bottom and side surfaces of the trench, into which a conductive material may be filled to form a conductive arrangement 210′.

In the embodiment shown in FIGS. 1-4, no side diffusion barrier layer is formed on the side walls of the trench. However, generally the conductive diffusion barrier layer 208, 208′ is deposited in such a manner that a portion thereof on the side walls of the trench is thinner than a portion thereof on the bottom of the trench, due to process limits. Therefore, the formed side diffusion barrier layer can mitigate or even eliminate the disadvantage that the portion of the conductive diffusion barrier layer on the side walls of the trench is relatively thinner. As can be seen from FIG. 8, the metal interconnect arrangement according to this embodiment can further prevent inter-diffusion between the conductive material of the conductive arrangement 210′ and the first ILD 204′.

Furthermore, according to an embodiment, a further diffusion barrier layer 212 may be further formed on a top surface of the first interconnect layer 20′. Likewise, the further diffusion barrier layer 212 may comprise insulating amorphous carbon. In this way, the barrier layers (i.e., the first diffusion barrier layer 202′, the side diffusion barrier layer 207′, the further diffusion barrier layer 212, and the conductive barrier layer 208′) may surround almost all portions of the conductive arrangement 210′, which otherwise would contact the dielectric layers. As a result, it is possible to more effectively prevent the conductive material of the conductive arrangement 210′ from diffusing into the dielectric layers.

Certainly, further interconnect layers may be formed on the first interconnect layer 20′ shown in FIG. 8, for example, in a way as described above with reference to FIGS. 3 and 4. Further, in manufacturing those interconnect layers, side diffusion barrier layers may also be formed on side surfaces of conductive arrangements of the respective interconnect layers. For example, this may be achieved by forming a diffusion barrier layer on side surfaces of a trench when the trench has been formed by patterning.

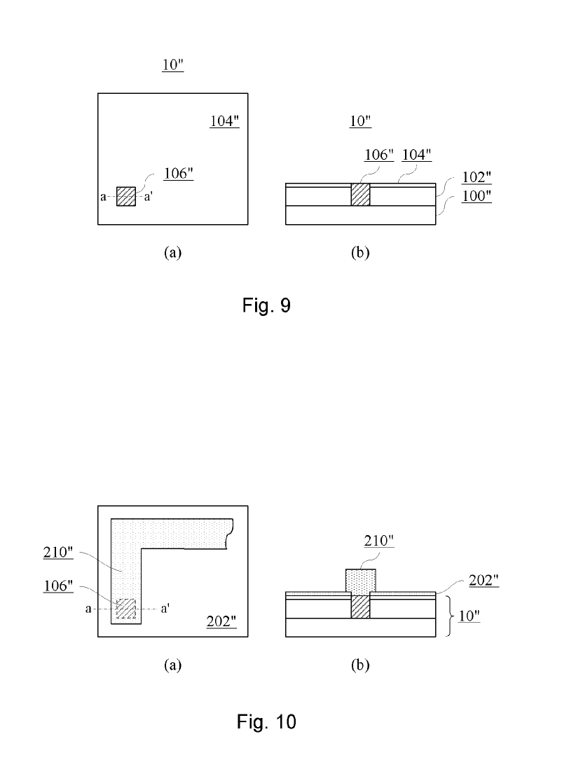

Next, a flow of manufacturing a metal interconnect arrangement according to a still further embodiment of the present disclosure will be described with reference to FIGS. 9-13. This flow according to the still further embodiment differs from the flows according to the above embodiments manly in the sequence of forming a conductive arrangement and forming an ILD. In the following, descriptions are provided mainly with respect to differences of this embodiment from the above embodiments. Further, reference symbols “xx″” shown in FIGS. 9-13 refer to the same components as those indicated by reference symbols “xx” in FIGS. 1-4.

Likewise, FIG. 9 schematically shows a general semiconductor arrangement 10″ after the FEOL. The semiconductor arrangement 10″ is identical to the semiconductor arrangement 10 shown in FIG. 1. For components of the semiconductor arrangement 10″, reference may be made to the above descriptions in conjunction with FIG. 1, and detailed descriptions thereof are omitted here.

Next, as shown in FIG. 10, a first diffusion barrier layer 202″ may be formed on the semiconductor arrangement 10″ by means of deposition, for example. The first diffusion barrier layer 202″ may be patterned by means of, for example, photolithography, to form a first opening at a position corresponding to a contact 106″. In this way, a conductive arrangement to be formed later can be electrically connected to the contact 106″ through the first opening. After that, a patterned conductive arrangement 210″ may be formed on the first diffusion barrier layer 202″. For example, the patterned conductive arrangement 210″ may be achieved by depositing a layer of conductive material on the first diffusion barrier layer 202″ and then patterning this layer by photolithography. In the example shown in FIG. 10, the patterned conductive arrangement 210″ is shown as an inverted-L shape. However, the present disclosure is not limited thereto, as described above.

Subsequently, as shown in FIG. 11, a first ILD 204″ may be formed on the first diffusion barrier layer 202″ by means of deposition, for example. According to an embodiment, the first ILD 204″ may comprise insulating amorphous carbon. Thus, the first ILD 204″ may serve as an ILD, and on the other hand as a diffusion barrier layer. Here, preferably the first ILD 204″ covers the conductive arrangement 210″. In this way, the conductive arrangement 210″ has substantially all its surfaces covered by the first diffusion barrier layer 202″ and the first ILD 204″. As a result, it is possible to more effectively prevent inter-diffusion between the conductive material of the conductive arrangement 210″ and its adjacent dielectric layers. Then, a first interconnect layer 20″ is achieved.

After formation of the first interconnect layer 20″, further interconnect layers may be further formed thereon. For example, as shown in FIG. 11, a second ILD 304″ and an optional stop/protection layer 306″ may be formed sequentially on the first interconnect layer 20″. It is to be noted that formation of a second diffusion barrier layer is not necessary before formation of the second ILD 304″ because the first ILD 204″ covers the conductive arrangement 210″ as described above (that is, the first interconnect layer 20″ has its top surface covered by a diffusion barrier). However, the present disclosure is not limited thereto. For example, in forming the first interconnect layer 20″, the first ILD 204″ may be subjected to planarization such as CMP, to expose the top surface of the conductive arrangement 210″. In this case, the second diffusion barrier layer (which may also comprise insulating amorphous carbon) may be formed before the formation of the second ILD 304″.

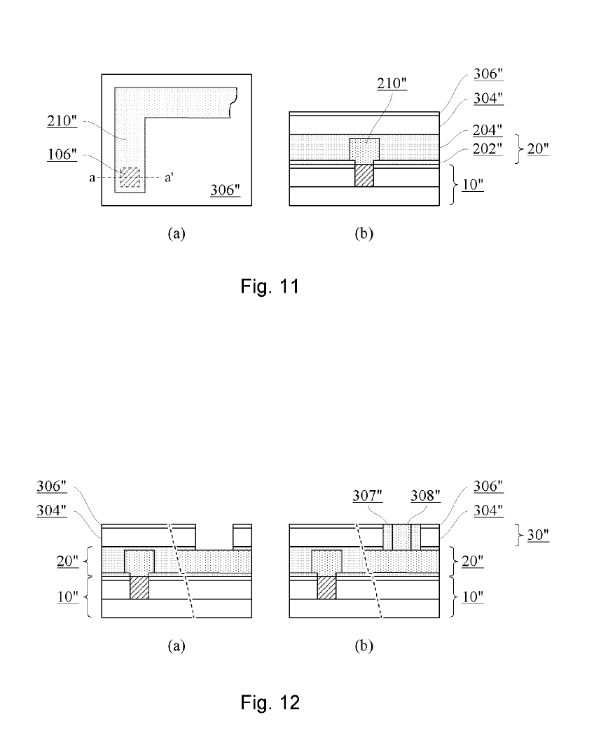

Then, as shown in FIG. 12(a), a pattern corresponding to a conductive arrangement to be formed in a second interconnect layer may be transferred to the stop/protection layer 306″ and the second ILD 304″ by means of, for example, photolithography, to form a trench therein. Next, as shown in FIG. 12(b), a side diffusion barrier layer 307″ may be formed on side surfaces of the trench, and then a conductive material may be filled into the trench to form a conductive arrangement 308″. In this way, the second interconnect layer 30″ is achieved.

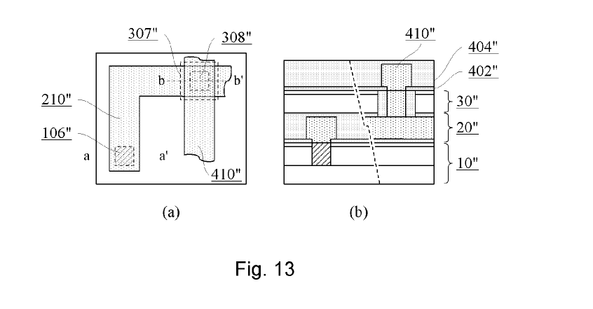

Next, as shown in FIG. 13, a third interconnect layer may be further formed. Specifically, as shown in FIG. 13, a third diffusion barrier layer 402″ may be formed on the second interconnect layer 30″, and then patterned to form an opening at a position corresponding to the second conductive arrangement 308″. After that, a third patterned conductive arrangement 410″ and then a third ILD 404″ may be formed on the third diffusion barrier layer 402″. Likewise, the third ILD 404″ may comprise insulating amorphous carbon, and thus can also serve as a diffusion barrier. Preferably, the third ILD 404″ may cover the third patterned conductive arrangement 410″.

In the metal interconnect arrangement according to this embodiment, conductive barrier layers as those used in the above described embodiments can be eliminated.

According to an embodiment, a thin film of insulating amorphous carbon may be fabricated as follows. Specifically, a Filtered Cathodic Vacuum Arc Deposition (FCVAD) system can be adopted. A graphite target with a high purity, for example, greater than about 99%, and preferably greater than about 99.99%, may be provided. In the FCVAD system, a 90°-curved magnetic filter, or preferably a dual 90°-curved magnetic filter, may be used. For example, a voltage applied to the magnetic filter may be about 10V-about 100V, and preferably about 25V-about 50V, and an arc voltage may lie between about 20V-about 50V. A vacuum chamber has a pressure lower than about 1*10⁻² Pa, and preferably lower than about 1*10⁻³ Pa. A negative bias voltage applied to a silicon wafer may be about 0V-about 200V, and preferably about 10V-about 100V. The silicon wafer is separated from an outlet of the magnetic filter at a distance greater than about 200 mm, and preferably greater than 500 mm. Optionally, Ar gas may be passed into the vacuum chamber before depositing the insulating amorphous carbon film, but with the pressure within the vacuum chamber still lower than about 1*10⁻³ Pa, to slow down the deposition speed. It is to be noted that the insulating amorphous carbon film deposited by this method has no intended doping of H, O, Ar, and metal elements. The achieved thin film may comprise elements in trace amount, such as Mg, Al, Si, S, K, Ca, Ti, Fe, and Sr, which are impurities in the graphite target. The concentration of those elements can be further reduced by providing the graphite target with an even higher purity. The achieved film may have sp3 C—C bonds in a content of about 50%-about 90%, and have a density of about 2.8-3.4 g/cm³, which can be measured by mans of laser Raman spectrometry and X-ray photoelectron energy spectroscopy. Further, the achieve film may have a surface roughness less than about 1 nm, which can be measured by means of AFM.

Though in the above embodiments the diffusion barrier layer comprising insulating amorphous carbon is applied to the metal interconnect arrangement, the present disclosure is not limited thereto. Instead, the diffusion barrier layer comprising insulating amorphous carbon is applicable to any interface between a metal arrangement and a dielectric layer, to prevent inter-diffusion between the metal arrangement and the dielectric layer. The diffusion barrier layer comprising insulating amorphous carbon is particularly suitable for applications where a low dielectric constant and/or a good heat conduction are needed.

The mere fact that the various embodiments are described separately does not mean that means recited in the respective embodiments cannot be used in combination to advantage.

In the above descriptions, details of patterning and etching of the layers are not described. It is to be understood by those skilled in the art that various measures may be utilized to form the layers and regions in desired shapes. Further, to achieve the same feature, those skilled in the art can devise processes not entirely the same as those described above.

From the foregoing, it will be appreciated that specific embodiments of the disclosure have been described herein for purposes of illustration, but that various modifications may be made without deviating from the disclosure. In addition, many of the elements of one embodiment may be combined with other embodiments in addition to or in lieu of the elements of the other embodiments. Accordingly, the technology is not limited except as by the appended claims.

1. A metal interconnect arrangement, comprising:
a conductive plug/interconnect wire for electrical connection; and
a diffusion barrier layer provided on at least a portion of a surface of the conductive plug/interconnect wire,
wherein the diffusion barrier layer comprises insulating amorphous carbon.

2. The metal interconnect arrangement according to claim 1, further comprising a dielectric layer, wherein the conductive plug/interconnect wire is embedded in the dielectric layer.

3. The metal interconnect arrangement according to claim 2, wherein the diffusion barrier layer is provided on at least one of:
a bottom surface of the dielectric layer, wherein the conductive plug/interconnect wire is electrically connected to an underlying conductive arrangement through an opening in the diffusion barrier layer;
a side surface of the dielectric layer; and
a top surface of the dielectric layer, wherein the conductive plug/interconnect wire is electrically connected to an overlying conductive arrangement through an opening in the diffusion barrier layer.

4. The metal interconnect arrangement according to claim 1, further comprising a conductive barrier layer surrounding bottom and side surfaces of the conductive plug/interconnect wire.

5. The metal interconnect arrangement according to claim 2, wherein the dielectric layer comprises insulating amorphous carbon.

6. The metal interconnect arrangement according to claim 5, wherein the dielectric layer and the diffusion barrier layer are formed integrally.

7. The metal interconnect arrangement according to claim 2, wherein the dielectric layer comprises low-K dielectric.

8. The metal interconnect arrangement according to claim 7, wherein the low-K dielectric has a dielectric constant K<3.5, preferably K<3.0, and more preferably K<2.0.

9. The metal interconnect arrangement according to claim 2, wherein the diffusion barrier layer has a thickness of 2-200 nm, and preferably 5-50 nm.

10. A method of manufacturing a metal interconnect arrangement comprising a conductive plug/interconnect wire for electrical connection, the method comprising:
forming a diffusion barrier layer on at least a portion of a surface of the conductive plug/interconnect wire,
wherein the diffusion barrier layer comprises insulating amorphous carbon.

11. The method according to claim 10, wherein
the conductive plug/interconnect wire is embedded in a dielectric layer; and
forming the diffusion barrier layer comprising:
providing a preliminary diffusion barrier layer on a bottom surface of the dielectric layer;
patterning the dielectric layer and the preliminary diffusion barrier layer to form a trench therein; and
filling a conductive material into the trench to form the conductive plug/interconnect wire,
wherein the preliminary diffusion barrier layer is patterned to have an opening therein, through which the conductive plug/interconnect wire is electrically connected to an underlying conductive arrangement, and wherein the patterned preliminary diffusion barrier layer constitutes the diffusion barrier layer.

12. The method according to claim 11, wherein before filling of the conductive material, the method further comprises:
forming a side diffusion barrier layer on side surfaces of the trench, wherein the side diffusion barrier layer comprising insulating amorphous carbon.

13. The method according to claim 10, wherein
the conductive plug/interconnect wire is embedded in a dielectric layer; and
forming the diffusion barrier layer comprising:
patterning the dielectric layer to form a trench therein;
forming the diffusion barrier layer on side walls of the trench; and
filling a conductive material into the trench to form the conductive plug/interconnect wire,

14. The method according to claim 11, wherein before filling of the conductive material, the method further comprises:
forming a conductive barrier layer on bottom and side surfaces of the trench.

15. The method according to claim 10, wherein
the conductive plug/interconnect wire is embedded in a dielectric layer; and
forming the diffusion barrier layer comprising:
providing a preliminary diffusion barrier layer on a top surface of the dielectric layer; and
patterning the preliminary diffusion barrier layer to form the diffusion barrier layer,
wherein the preliminary diffusion barrier layer is patterned to have an opening therein, through which the conductive plug/interconnect wire is electrically connected to an overlying conductive arrangement.

16. A diffusion barrier layer, provided between a metal arrangement and a dielectric material to prevent inter-diffusion between the metal arrangement and the dielectric material, wherein the diffusion barrier layer comprises insulating amorphous carbon.

17. The method according to claim 13, wherein before filling of the conductive material, the method further comprises:
forming a conductive barrier layer on bottom and side surfaces of the trench.
